(19) United States
(12) Patent Application Publication
(10) Pub. No.: US 2006/0192275 A1
(43) Pub. Date: Aug. 31, 2006

(54) Encapsulation method for semiconductor device having center pad

(75) Inventors: Seongmin Lee, Seoul (KR); Hangcheol Choi, Ichon-si (KR); In-Sang Yoon, Ichon-si (KR)

Correspondence Address: HAYNES BEFFEL & WOLFELD LLP, P O BOX 366, HALF MOON BAY, CA, 94019, US

(73) Assignee: ChipPAC. Inc, Fremont, CA (US)

(21) Appl. No.: 11/274,489

(22) Filed: Nov. 14, 2005

Related U.S. Application Data
(60) Provisional application No. 60/627,936, filed on Nov. 13, 2004.

(51) Int. Cl. H01L 23/495

(52) U.S. Cl. 257/668

(57) ABSTRACT

Apparatus and center pad die and substrate assemblies configured to provide for molding, in a single molding step, both an attached center pad die and other features on a die attach side of the substrate, and wire bonds an associated bond pads and other features on the opposite side of the substrate. Also, methods for sealing a center pad die and substrate assembly, including such a molding step.

### CROSS REFERENCE TO RELATED APPLICATION

This application claims the benefit of U.S. Provisional Application No. 60/627,650, filed Nov. 13, 2004, titled “Wire bonding system for integrated circuits, which is hereby incorporated by reference.

### BACKGROUND

This invention relates to semiconductor packaging.

Generally a semiconductor package includes a semiconductor die attached to, and electrically connected to conductive traces on, a substrate. Wire bonding is one method of forming electrical connections between the die and the substrate. For a conventional wire bond interconnect between pads on the die and the traces on the substrate, the die is mounted with the active side facing away the substrate, and wires are ball bonded at one end to the die pads and are wedge or stitch bonded at the other end to bond sites on lead fingers or pads on the side of the substrate on which the die is attached.

The wires and their interconnections to the die and the substrate must be protected (or sealed), and packages are commonly protected by encapsulation or molding, using an encapsulation material or molding compound. Sealing using a molding compound may be referred to as molding; sealing using liquid resin may be referred to as encapsulation.

The conventional approach to sealing chip scale packages (CSP) is by transfer molding using a curable mold compound to accomplish high reliability, high productivity and low material cost.

Generally, the mold consists of an upper mold chase and a lower mold chase. Die and substrate assemblies are usually provided as a row or an array of several die attached and wire bonded to a substrate strip or sheet. The margin of the strip or sheet is clamped between the edges of the upper and lower chase, and the molding compound is injected into the cavity surrounding the die and substrate assemblies.

The molded features include the semiconductor device (die), the wires (usually gold or aluminum) and the bond fingers on the substrate. In many semiconductor devices the die pads are arranged in one or more rows near the margin of the die. However, some semiconductor devices, for example some memory die such as SDRAM die, have bonding pads extending not along perimeter of active surface of the die, but in one or more rows across central parts of the active surface (so-called center pad die). The functionalities of the kinds of die that have central pads often require that the wires be made as short as possible to reduce signal time delay. But it is difficult to meet this requirement with a conventional molding method because the wires must be long enough to reach beyond the die edge, and the gold wire length becomes longer as the bond pad position is shifted from the perimeter to central parts of device.

In one approach to shortening the wire length in center pad die, the die is mounted with the active side facing toward the substrate, and the substrate is provided with a slot at the position where the center pads are located on the die. That is, the pads (and typically some area of the active side of the die next to the pads) could be seen through the slot following the die mount step. The bond fingers or bond pads are on the side of the substrate opposite the die attach side, that is, on the side facing away from the die. The wire bonding is carried out by connecting the wires from the pads on the die, through the slot, to the bond fingers or pads. The bond fingers or pads can be positioned on the substrate surface near the edges of the slot, so that the wire lengths can be made very short. In packages having this arrangement, the backside of the die is exposed, facing away from one side of the substrate; and the die pads and wires and bond fingers or pads in areas of the substrate adjacent the slot are on the opposite side of the substrate. In some instances it may be acceptable to protect (by molding or encapsulation) only the wires and die pads and bond fingers. However, where it is desirable to protect the wires and pads and bond fingers or bond pads as well as the backside of the die, it is necessary to perform two separate molding operations, one for the die attach side of the substrate and the other for the wire bond side of the substrate. This two step process increases processing time and materials cost.

### SUMMARY

According to one aspect of the invention, the substrate is provided at each die mounting location with a slot which is long enough to extend beyond the attached center pad die. The array or row of center pad die and substrate assemblies is clamped between an upper mold chase and a lower mold chase. The molding compound is introduced to a part of the mold cavity (such as an upper chase cavity) that contains the features situated on one side of the substrate, and then the mold cavity flows through the slot to the part of the mold cavity (such as a lower chase cavity) that contains the features on the opposite side of the substrate. Thus, according to the invention, molding of features on both sides of the substrate can be accomplished in a single molding step.

According to another aspect of the invention, a lower chase block is provided with trenches which constitute mold cavities each configured and dimensioned to accommodate wire bonds passing through the slot in the substrate, and associated pads and bond fingers.

The invention features, in another aspect, a lower mold chase set having a plurality of cavities each configured and dimensioned to accommodate the active side of a center pad device and the associated wires and bond fingers or pads in the substrate adjacent the slot in the substrate.

In another general aspect the invention features a method for sealing a center pad die and substrate assembly, by providing a slot in a die attach region of the substrate, the slot having a width sufficient to accommodate wire bonds passing from bond pads on a die, and having a length greater than a dimension of a die to be mounted on the die attach region, so that the spot projects beyond at least one edge of a mounted die. The opening through the assembly provided by the slot is made sufficiently large to permit a flow of mold compound through the slot during a mold flow step of the method.

In another general aspect the invention features a center pad die and substrate assembly having a slot in the die attach region of the substrate, the slot having a width sufficient to accommodate wire bonds passing from bond pads on a die, and having a length greater than a dimension of a die to be mounted on the die attach region, so that the spot projects beyond at least one edge of a mounted die.

### BRIEF DESCRIPTION OF THE DRAWINGS

FIG. 1A is a diagrammatic sketch in a plan view showing parts of an upper mold chase for use in molding a conventional wire bond die and substrate assembly.

FIG. 1B is a diagrammatic sketch in a sectional view showing a section thru part of the upper mold chase as in FIG. 1A, at 1B-1B.

FIG. 1C is a diagrammatic sketch in a sectional view showing a section thru part of the upper mold chase as in FIG. 1A, at 1C-1C.

FIG. 2A is a diagrammatic sketch in a plan view showing parts of a lower mold chase for use in molding a conventional wire bond die and substrate assembly.

FIG. 2B is a diagrammatic sketch in a sectional view showing a section thru part of the lower mold chase as in FIG. 2A, at 2B-2B.

FIG. 2C is a diagrammatic sketch in a sectional view showing a section thru part of the lower mold chase as in FIG. 2A, at 2C-2C.

FIG. 3A is a diagrammatic sketch in a plan view showing parts of an upper mold chase for use in molding a center pad wire bond die and substrate assembly according to the invention.

FIG. 3B is a diagrammatic sketch in a sectional view showing a section thru part of the upper mold chase as in FIG. 3A, at 3B-3B.

FIG. 3C is a diagrammatic sketch in a sectional view showing a section thru part of the upper mold chase as in FIG. 3A, at 3C-3C.

FIG. 4A is a diagrammatic sketch in a plan view showing parts of a lower mold chase for use in molding a center pad wire bond die and substrate assembly according to the invention.

FIG. 4B is a diagrammatic sketch in a sectional view showing a section thru part of the lower mold chase as in FIG. 4A, at 4B-4B.

FIG. 4C is a diagrammatic sketch in a sectional view showing a section thru part of the lower mold chase as in FIG. 4A, at 4C-4C.

FIG. 5A is a diagrammatic sketch in a plan view showing center pad die mounted on a conventional slotted substrate.

FIG. 5B is a portion of the sketch of FIG. 5A, enlarged to show the relation of the slot and the die.

FIG. 6A is a diagrammatic sketch in a plan view showing center pad die mounted on a slotted substrate having a long slot at the die attach region and an additional slot, according to embodiment of the invention.

FIG. 6B is a portion of the sketch of FIG. 6A, enlarged to show the relation of the slots and the die.

FIG. 6C is a diagrammatic sketch showing a portion of a die and substrate assembly according to another embodiment of the invention, enlarged as in FIG. 6B, in a plan view showing center pad die mounted on a slotted substrate having a long slot at the die attach region and no additional slot.

FIGS. 7A-7C are diagrammatic sketches in a sectional view thru a mold in use for a molding operation, showing a flow of the molding compound.

FIGS. 8A, 8B, and 8C are diagrammatic sketches in sectional view thru a center pad die package at various processing stages. FIG. 8A shows stages of the process according to the invention; FIG. 8B shows stages in a conventional process of the type having an encapsulation step but leaving the passive side of the die exposed; FIG. 8C shows stages in a conventional process of the type having an encapsulation step for the active side of the die and a molding step for the backside of the die and substrate.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs.

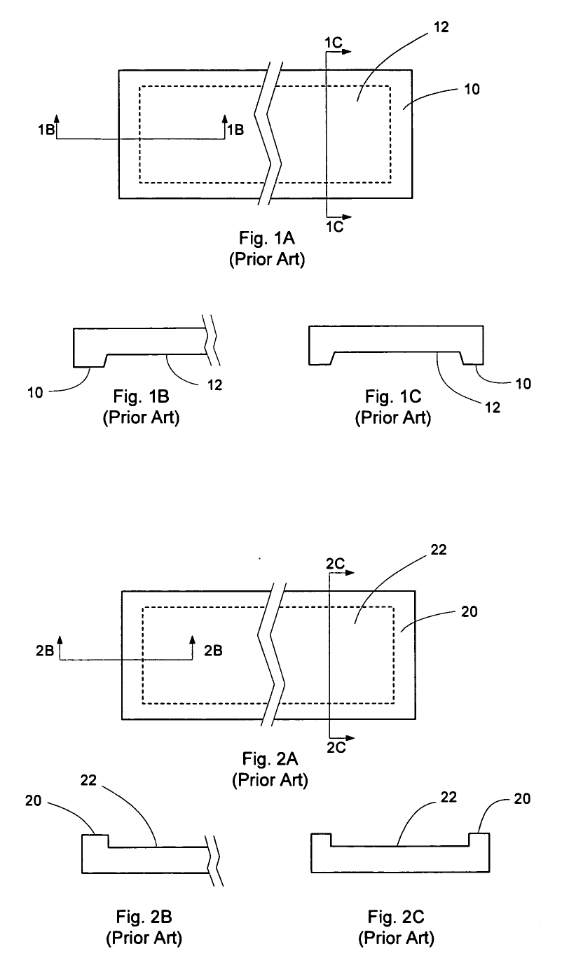

FIGS. 1A, 1B and 1C show schematically a conventional upper mold chase set and FIGS. 2A, 2B and 2C show schematically a matching conventional lower chase set such as may be used for molding a CSP. Only the upper chase has a molding cavity because all the features of the die and substrate assembly that should be protected by the molding compound are located on the same side (the upper side, in relation to the mold cavity) of the substrate. The upper mold chase set has a cavity 12 defined by a raised margin 10. The lower mold chase set has a (comparatively much thinner) cavity 22 defined by a slightly raised margin 20. The assemblies to be molded are provided as a row or an array of die attached to a substrate strip or sheet having a corresponding row or array of substrates; the die are wire bonded to bond sites in the side of the substrate to which the die are attached. The strip or sheet is placed between the upper and lower mold chases, with the die and wires and associated pads facing the upper mold chase and projecting into the cavity 12. The substrate strip or sheet is clamped at its edges between the margin 10 of the upper mold chase and the margin 20 of the lower mold chase, and the molding compound is introduced through a gate (not shown) into the cavity 12 over the substrate, where it envelops the die attach side of the substrate and the features that are attached to it. The cavity 12 is made deep enough (in the z-direction) to permit accommodate the loop height of the wires, plus an additional depth over the wires. The cavity 22 is deep enough only to accommodate irregularities in the side of the substrate opposite the die attach side, typically about 5-10 μm, for example.

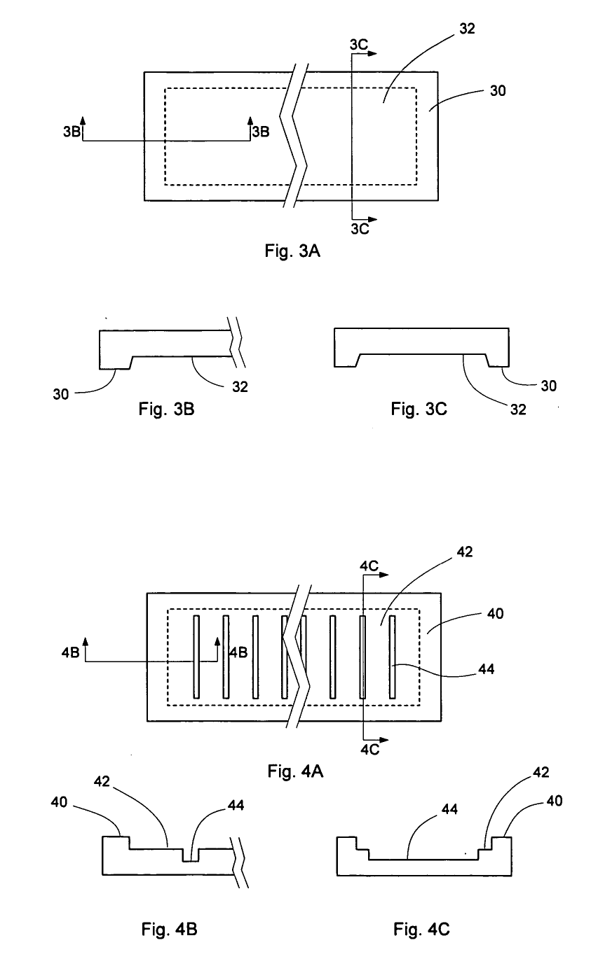

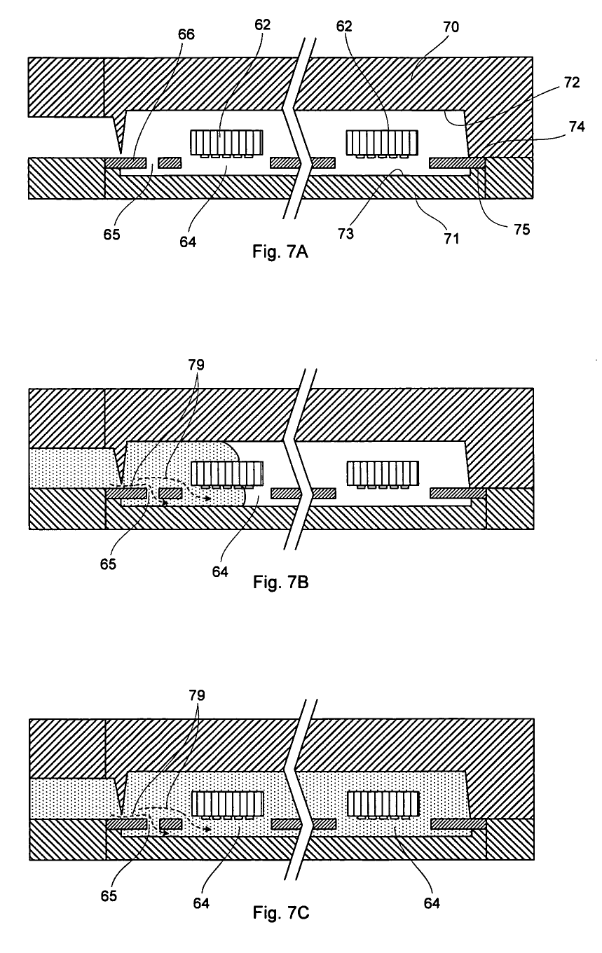

FIGS. 3A, 3B and 3C show schematically an upper mold chase set and FIGS. 4A, 4B and 4C show schematically a matching lower chase set according to the invention, such as may be used for one-step molding of a center die package. The upper mold chase set can be configured much as the conventional upper mold chase set as in FIGS. 1A-1C. The upper mold chase set has a cavity 32 defined by a raised margin 30. The lower chase set of the invention is similar to the conventional lower chase set, having a thin cavity 42 defined by a slightly raised margin 40; but in the lower mold chase according to the invention trenches are provided as lower mold cavities 44 in the floor of the thin cavity 42. These lower mold cavities are configured and dimensioned to accommodate the wire bonds and associated features adjacent the slot in the substrate of a die and substrate assembly having center pad die wire bonded through slots in the substrate, as described more fully with reference to FIGS. 6A, 6B and 6C.

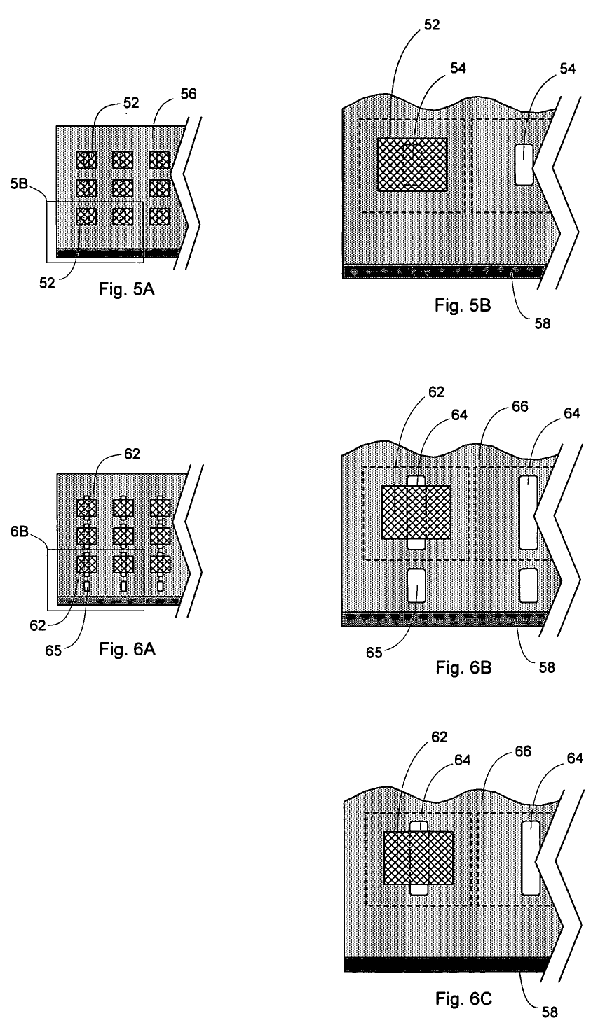

FIGS. 5A and 5B show a conventional center pad die and substrate assembly, in which the center pad die 52 (an array of die are mounted on an array of substrates on a substrate strip 56 in this example) is mounted on the substrate 56 with the active side toward the substrate, and with the die pads situated over a slot 54 in the substrate, so that the wire bonds pass from the die pads through the slot to bond fingers or pads on the substrate adjacent the slot. The location of a mold gate, through which the molding compound flows into the cavity over the substrate and features mounted on it, is indicated at 58.

FIGS. 6A, and 6B and 6C show center pad die and substrate assemblies according to two embodiments of the invention. According to the invention, the slots 64 beneath the die 62 are longer than the dimension of the overlying die, so that end portions of the slot open beyond the die edge. Additionally, in the assembly of FIGS. 6A and 6B the substrate is also provided with a row of slots 65 along the substrate margin near the mold gate location 68.

The slots allow the mold compound to flow through the substrate, as shown in stages in sectional views in FIGS. 7A, 7B and 7C. Referring to FIG. 7A, an upper cavity 72 is defined in the upper mold chase 70 by a raised margin 74. A thin lower cavity is defined in the lower mold chase 71 by a slightly raised margin 75, and a lower mold cavity is formed as a trench 73 in the lower chase. The substrate strip 66 is with the center pad die 62 and substrate 66 assemblies facing toward the lower chase is aligned so that the slots 64 in the substrate through which the wires pass (the wires are not shown in the FIGs.) overlie the trenches 73. The properly aligned substrate strip is clamped between the margins 74 and 75, and mold compound is allowed to flow through the gate and into and throughout the upper cavity, and through the slots 64 (and 65, in embodiments having the additional slots) into the trenches 73, as shown by the broken arrows 79 in FIGS. 7B and 7C. The molding compound filling the upper cavity molds the die, including the passive surface, and other features on the die attach side of the substrate; and, in the same molding step, the molding compound filling the trenches molds the portion of the active side of the die that overlies the slot in the substrate, as well as the wires and the wire bond sites on the lower side of the substrate next to the slot in the substrate.

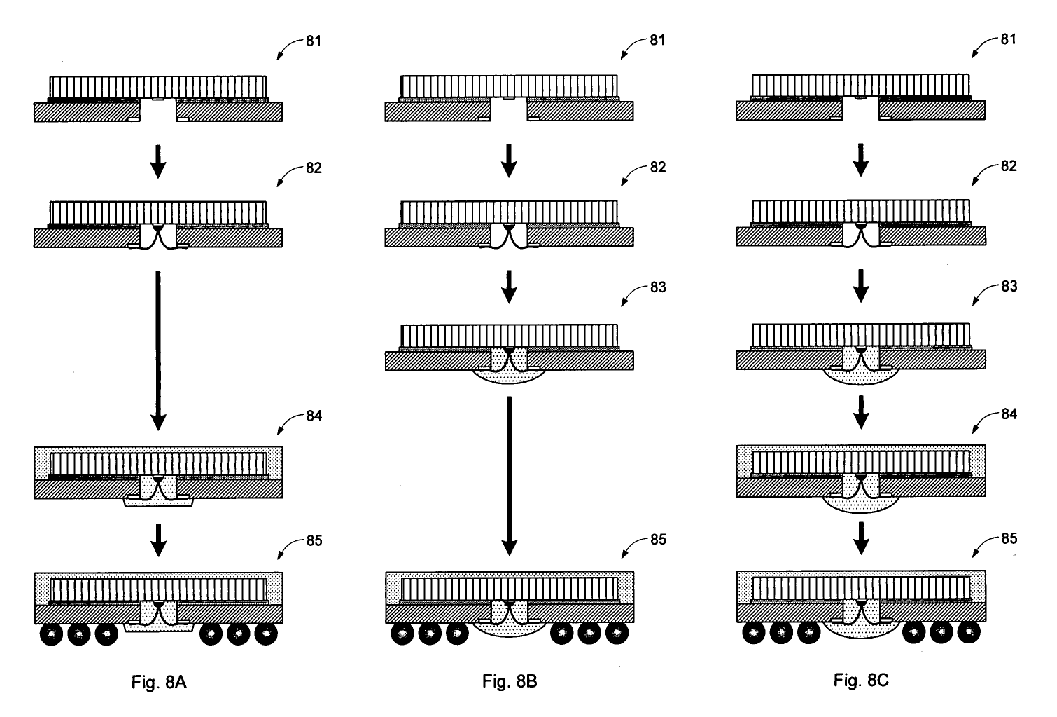

Stages in a process according to the invention are illustrated in FIG. 8A, for comparison with stages in conventional center pad die processes, shown in FIGS. 8B and 8C. Process stages shown in these FIGs. include die attach 81, wire bonding through the slot in the substrate 82, encapsulation 83, molding 84, and ball mount and saw singulation 85. As the FIGs. show, the type I conventional method employs encapsulation (not molding) to fill the slot in the substrate and to cover the wires and associated features on the lower side of the substrate, and to provide a fillet around the die while leaving the backside of the die exposed. The type II conventional method employs an encapsulation step to (not molding) to fill the slot in the substrate and to cover the wires and associated features on the lower side of the substrate; and employs a molding step to enclose the die, including the backside of the die. By contrast, the method according to the invention employs a single molding step to mold both the die (including the backside if the die) and to mold the wires and associated features on the lower side of the substrate.

1. A center pad die and substrate assembly wherein the substrate is provided at a die mounting location with a slot, the slot being long enough to extend beyond the attached die.

2. A method for sealing a center pad die and substrate assembly, comprising providing a an assembly as in claim 1, clamping the assembly between an upper mold chase and a lower mold chase, introducing molding compound to a first mold cavity that contains the features situated on one side of the substrate, the mold compound flowing through the slot to the part a second mold cavity that contains the features on an opposite side of the substrate.

3. A lower mold chase block, comprising trenches each constituting a mold cavity configured and dimensioned to accommodate wire bonds passing through a slot in the substrate of a center pad die and substrate assembly as in claim 1, and associated pads and bond fingers.

4. A method for sealing a center pad die and substrate assembly, comprising providing a slot in a die attach region of a substrate, the slot having a width sufficient to accommodate wire bonds passing from bond pads on a die to be mounted on a die attach region of the substrate, the slot having a length greater than a dimension of the die to be mounted on the die attach region, so that the spot projects beyond at least one edge of a mounted die; and causing mold compound to flow through the projecting portion of the slot.
